(19) United States
(12) Patent Application Publication
(10) Pub. No.: US 2018/0061613 A1
(43) Pub. Date: Mar. 1, 2018

(54) CHARGED-PARTICLE MICROSCOPE WITH EXCHANGEABLE POLE PIECE EXTENDING ELEMENT

(71) Applicant: FEI Company, Hillsboro, OR (US)

(72) Inventors: Bohuslav Sed'a, Blansko (CZ); Lubomír Tuma, Brno (CZ); Petr Hlavenka, Brno (CZ); Marek Uncovský, Brno (CZ); Radovan Vasina, Brno (CZ); Jan Trojek, Brno (CZ); Mostafa Maazouz, Hillsboro, OR (US)

(73) Assignee: FEI Company

(21) Appl. No.: 15/683,734

(22) Filed: Aug. 22, 2017

(30) Foreign Application Priority Data
Aug. 25, 2016 (EP) 16185627.3

(51) Int. Cl. H01J 37/26; H01J 37/20; H01J 37/244

(52) U.S. Cl. CPC H01J 37/261; H01J 37/244; H01J 37/20

(57) ABSTRACT

A charged-particle microscope having a vacuum chamber comprises a specimen holder, a particle-optical column, a detector and an exchangeable column extending element. The specimen holder is for holding a specimen. The particle-optical column is for producing and directing a beam of charged particles along an axis so as to irradiate the specimen. The column has a terminal pole piece at an extremity facing the specimen holder. The detector is for detecting a flux of radiation emanating from the specimen in response to irradiation by the beam. The exchangeable column extending element is magnetically mounted on the pole piece in a space between the pole piece and the specimen holder. Methods of using the microscope are also disclosed.

### CROSS REFERENCE TO RELATED APPLICATION

The present application claims priority from pending European Patent Application No. 16185627.3, filed Aug. 25, 2016, which is incorporated herein by reference.

The invention relates to a charged-particle microscope having a vacuum chamber comprising:
A specimen holder, for holding a specimen;
A particle-optical column, for producing and directing a beam of charged particles along an axis so as to irradiate the specimen, said column having a terminal pole piece at an extremity facing said specimen holder;
A detector, for detecting a flux of radiation emanating from the specimen in response to irradiation by said beam.

The invention also relates to a method of using such a charged-particle microscope.

Charged-particle microscopy is a well-known and increasingly important technique for imaging microscopic objects, particularly in the form of electron microscopy. Historically, the basic genus of electron microscope has undergone evolution into a number of well-known apparatus species, such as the Transmission Electron Microscope (TEM), Scanning Electron Microscope (SEM), and Scanning Transmission Electron Microscope (STEM), and also into various sub-species, such as so-called “dual-beam” tools (e.g. a FIB-SEM), which additionally employ a “machining” Focused Ion Beam (FIB), allowing supportive activities such as ion-beam milling or Ion-Beam-Induced Deposition (IBID), for example. More specifically:
In a SEM, irradiation of a specimen by a scanning electron beam precipitates emanation of “auxiliary” radiation from the specimen, in the form of secondary electrons, backscattered electrons, X-rays and cathodoluminescence (infrared, visible and/or ultraviolet photons), for example; one or more components of this emanating radiation is/are then detected and used for image accumulation purposes.
In a TEM, the electron beam used to irradiate the specimen is chosen to be of a high-enough energy to penetrate the specimen (which, to this end, will generally be thinner than in the case of a SEM specimen); the transmitted electrons emanating from the specimen can then be used to create an image. When such a TEM is operated in scanning mode (thus becoming a STEM), the image in question will be accumulated during a scanning motion of the irradiating electron beam.
   More information on some of the topics elucidated here can, for example, be gleaned from the following Wikipedia links:
   http://en.wikipedia.org/wiki/Electon_microscope
   http://en.wikipedia.org/wiki/Scanning_electon_microscope
   http://en.wikipedia.org/wiki/Transmission_electon_microscopy
   http://en.wikipedia.org/wiki/Scanning_transmission_electron_microscopy
   As an alternative to the use of electrons as irradiating beam, charged particle microscopy can also be performed using other species of charged particle. In this respect, the phrase “charged particle” should be broadly interpreted as encompassing electrons, positive ions (e.g. Ga or He ions), negative ions, protons and positrons, for instance. As regards non-electron-based charged particle microscopy, some further information can, for example, be gleaned from references such as the following:
   https://en.wikipedia.org/wiki/Focused_ion_beam
   http://en.wikipedia.org/wiki/Scanning_Helium_Ion_Microscope
W. H. Escovitz, T. R. Fox and R. Levi-Setti, Scanning Transmission Ion Microscope with a Field Ion Source, Proc. Nat. Acad. Sci. USA 72(5), pp 1826-1828 (1975).
   http://www.ncbi.nlm.nih.gov/pubmed/22472444
   It should be noted that, in addition to imaging and performing (localized) surface modification (e.g. milling, etching, deposition, etc.), a charged particle microscope may also have other functionalities, such as performing spectroscopy, examining diffractograms, etc.

In all cases, a Charged-Particle Microscope (CPM) will comprise at least the following components:
A particle-optical column (illuminator), comprising a radiation source such as a Schottky electron source or ion gun, for instance, and serving to manipulate a “raw” radiation beam from the source and perform upon it certain operations such as focusing, aberration mitigation, cropping (with an aperture), filtering, etc. It will generally comprise one or more (charged-particle) lenses, and may comprise other types of (particle-)optical component also. If desired, the illuminator can be provided with a deflector system that can be invoked to cause its exit beam to perform a scanning motion across the specimen being investigated.
A specimen holder, on which a specimen under investigation can be held and positioned (e.g. tilted, rotated). If desired, this holder can be moved so as to effect scanning motion of the beam w.r.t. the specimen. In general, such a specimen holder will be connected to a positioning system.
A detector (for detecting radiation emanating from an irradiated specimen), which may be unitary or compound/distributed in nature, and which can take many different forms, depending on the radiation being detected. Examples include photodiodes, CMOS detectors, CCD detectors, photovoltaic cells, X-ray detectors (such as Silicon Drift Detectors and Si(Li) detectors), etc. In general, a CPM may comprise several different types of detector, selections of which can be invoked in different situations.

In the particular case of a dual-beam microscope, there will be (at least) two particle-optical columns, for producing and directing (at least) two different species of charged particle. Commonly, an electron column (arranged vertically) will be used to image the specimen, and an ion column (arranged at an angle) will be used to (concurrently) machine/process the specimen, whereby the specimen holder can be positioned in multiple degrees of freedom so as to suitably “present” a surface of the specimen to the employed electron/ion beams.

In the case of a transmission-type microscope (such as a (S)TEM, for example), a CPM will additionally comprise:
An imaging system, which essentially takes charged particles that are transmitted through a specimen (plane) and directs (focuses) them onto analysis apparatus, such as a detection/imaging device, spectroscopic apparatus (such as an EELS device), etc. As with the illuminator referred to above, the imaging system may also perform other functions, such as aberration mitigation, cropping, filtering, etc., and it will generally comprise one or more charged-particle lenses and/or other types of particle-optical components.

In what follows, the invention may—by way of example—sometimes be set forth in the specific context of electron microscopy; however, such simplification is intended solely for clarity/illustrative purposes, and should not be interpreted as limiting.

It will be clear from the dissertation above that CPMs can in some ways be regarded as highly versatile instruments, allowing imaging, spectrum acquisition, diffractogram study, and specimen modification/machining, for example. However, at the same time, one can argue that they are relatively inflexible tools, inter alia because:
The employed optical columns are generally large and heavy, and very sensitive to misalignment, thereby forcing them to have a fixed configuration;
The working distance between the (lowermost portion of the) optical column and the specimen is typically very small, and cramped with instrumentation such as specimen holders/manipulators and detectors.

As a result, a given CPM is often sub-optimally configured for many types of studies, constraining the tool operator to “make the most of what he has”, and denying him a measure of flexibility that would allow him to optimally tailor tool parameters on a “per individual case” basis.

It is an object of the invention to address the issue identified above. More specifically, it is an object of the invention to provide a more versatile CPM than currently available. In particular, it is an object of the invention that such a CPM should have a significantly widened scala of operating configurations and aspects as compared to currently available CPMs.

These and other objects are achieved in a charged-particle microscope as set forth in the opening paragraph above, characterized in that an exchangeable column extending element is magnetically mounted on said pole piece in a space between said pole piece and said specimen holder. Put another way: a relatively small, extremal portion of the optical column nearest the specimen holder is de-mountable and exchangeable, and can be easily replaced by another variant thereof because the mounting (attachment) mechanism is magnetic. As will be set forth in detail below, a broad selection of different extending elements can be easily deployed, allowing hugely improved operating flexibility.

The invention's magnetic attachment mechanism (for the exchangeable extending elements) is particularly advantageous in that:
As already set forth above, the available space between the optical column and the specimen is typically extremely cramped, so there is little or no spare room to apply rotary force, as in the case of assistive tools such as screwdrivers or wrenches that would be needed to turn fastening structures such as screws or bolts. Similarly, use of a mechanical click/unclick fastening mechanism would require application of considerable insertive/extractive force to the extending element, requiring some form of strong assistive gripper, which would only increase cluttering and complexity.
On the other hand, exploitation of magnetic clamping effects can mitigate this problem.
   For example:
If the particle-optical column terminates with a magnetic lens, it is possible to exploit the terminal pole piece of the column as a yoke of an electromagnet circuit, which can be switched on/off so as to attract/release a (partially) ferromagnetic extending element placed beneath it;
Alternatively/supplementally, a (mating portion of) an extending element—and/or a receiving portion of the pole piece—can be provided with an integrated switchable electromagnet to achieve a similar effect (see below).
   In such scenarios, an extending element need only be (gently) held in place beneath the pole piece while the employed electromagnetic clamping is engaged, thereby effectively obviating the need for special mounting/de-mounting tools.

In general, it will be desirable to mount the extending element on a pre-determined portion of the pole piece, and in a pre-determined orientation. In order to quickly and easily achieve such alignment, a particular embodiment of the invention has the following features:
A receiving face of said pole piece is provided with a first mechanical aligning feature;
A mating face of said extending element is provided with a second mechanical aligning feature;
Said first and second mechanical aligning features engage with each other so as to cause the extending element to be held in a pre-defined position on the pole piece.
   Such an arrangement is effectively “self-aligning” in that, once the first and second aligning features are brought into mutual proximity, they tend to intrinsically “seek and engage” with each other, thereby autonomously forcing the extending element into a particular stance on the pole piece. In an advantageous example, one of the aligning features is concave in form (e.g. a cavity, with (quasi) hemi-spherical or conical geometry) and the other aligning feature is convex in form (e.g. a nipple, stub or other such protrusion) with a compatible geometry and dimensioning, which two features—once partially engaged—will tend to move and lock each other into a fully-mated configuration. In many applications, the pre-defined (mated) position referred to here will be substantially centered on said (particle-optical) axis—although this does not necessarily have to be the case.

According to a further aspect of an embodiment as set forth in the previous paragraph:
Said receiving face is provided with a first set of utilities interconnects;
Said mating face is provided with a second, corresponding set of utilities interconnects;
When said mechanical aligning features are engaged, said first and second sets of utilities interconnects are coupled to one another, so as to allow transfer of utilities between the pole piece and the extending element.
   Examples of utilities (and the corresponding interconnects) in this context include:
Electrical power/electrical signals, provided through electrical cables. The interconnects in this case might, for example, take the form of an electrode pad and cooperating spring-biased contact pin/block. Such an arrangement is useful if any component of the extending element (e.g. an electromagnet, auxiliary mini-lens, detector, etc.) needs to be electrically powered, read-out and/or controlled
Fluid, provided in a tube/pipe. The interconnects in this case might, for example, take the form of a spring-biased pressure contact with associated sealing collar. Such fluid might, for example, be used as a coolant, or administered from an orifice on the extending element as an alternative to use of a separate Gas Injection System (GIS).

In another important aspect of the present invention, an interface between said pole piece and said extending element forms a vacuum seal. This is advantageous if the gas pressure outside the optical column is relatively high, e.g. as in the case of a so-called environmental SEM or low-pressure SEM, in that it serves to keep environmental gas out of the interior of the particle-optical column. An adequate seal can, for example, be formed by ensuring that the mating surfaces of the pole piece and extending element are smooth/polished and (geometrically) conform precisely to one another: when such surfaces are pulled tightly together by the abovementioned magnetic coupling, they will intimately engage, without significant intervening gaps. Alternatively/supplementally, one can use some sort of compliant member between the two surfaces—such as an O-ring, washer, etc.—to produce a gastight seal.

Apart from the realization of a vacuum seal as described in the previous paragraph, another advantage of the inventive magnetic coupling is that it is mechanically (very) rigid/stiff. As a result, vibration/shift of a mounted extending element relative to its carrying pole piece is essentially negligible.

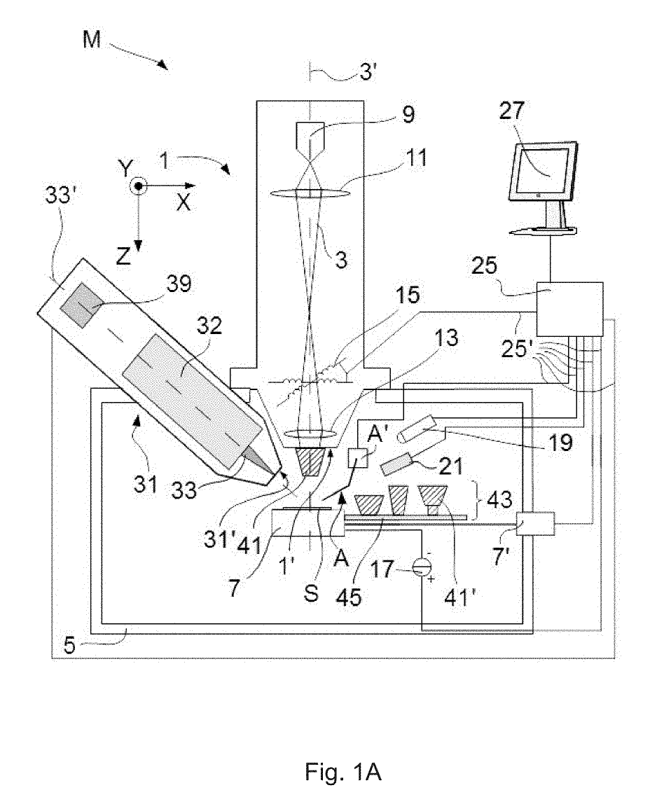

As already mentioned above, as regards possible mechanisms for enacting the magnetic coupling of the extending element to the pole piece, there are various possibilities to choose from. For example:
If the terminal pole piece in the column is part of a magnetic lens, then this will intrinsically produce a switchable magnetic field that will latch onto an offered (at least partially ferromagnetic) extending element; in a, specific example, an extending element may have at least a perimetric collar of ferromagnetic material around a mating face that abuts against the pole piece.
In situations where said terminal pole piece is (an electrode) part of an electrostatic lens (e.g. as in a FIB column), and/or in situations in which it is desirable to supplement the mechanism described in the previous item, one can employ one or more dedicated electromagnets in/on said receiving face of the pole piece and/or in/on/around said mating face of the extending element. As long as these electromagnets are configured to produce a field that is enclosed in a suitable magnetic circuit (and, therefore, does not extend into the beam path), they will not have a significant parasitic effect on the charged-particle beam: see FIG. 1C (inset), for example. If provided on the extending element, they may receive electrical power via an attached (shielded) “umbilical cord”, or via a set of engaging interconnects as set forth above.
Instead of using electromagnets (or as a supplement thereto), one could also consider using permanent magnets. In principle, this would require an exertion of force to decouple an extending element from a pole piece to which it was magnetically coupled; however, this could be obviated by incorporating an electromagnetic (into the pole piece and/or extending element) which could be activated/energized at will in order to cancel the attracting force produced by said permanent magnets.

In a highly versatile and convenient embodiment, a microscope according to the present invention further comprises:
An in situ library, for storing a variety of different extending elements;
An exchanger mechanism, for:
De-mounting an extending element from said pole piece and storing it in said library;
Retrieving an extending element from said library and mounting it on said pole piece. Such an embodiment allows a selection of different, commonly-used extending elements to be “parked” at a convenient location within the microscope's vacuum chamber, enabling them to be de-mounted/swapped/mounted in situ without having to break vacuum, thereby realizing a huge increase in achievable throughput and efficiency. The employed “library” may take any convenient form, such as a rack, carrousel or plate with designated “parking locations” (e.g. cut-outs, slots, cavities, etc.) for different extending elements. These parking locations may, if desired, be supplied with individual machine-readable markers/tags (such as a barcode, NFC (Near-Field Chip), etc.), to assist automated seek operations, or one may simply register/store positional coordinates of each parking location; in conjunction with an associated lookup table, such a set-up allows the exchanger mechanism to autonomously select/return an intended extending element from/to a designated parking location.

In a particular embodiment of a set-up as described in the previous paragraph, at least part of said exchanger mechanism is comprised in said specimen holder. For example:
A “peripheral” region of the specimen holder—not normally under the pole piece during specimen irradiation—could be provided with a tray on which various extending elements are arranged.
In order to swap extending elements, one could then:
Move the specimen holder so as to place a vacant tray position (closely) under a first extending element, currently mounted on the pole piece;
Deactivate the magnetic coupling that is holding said first extending element in place, thereby releasing it onto said vacant position;
Move the specimen holder so as to place a second extending element, currently at another parking location on the tray, (closely) underneath the pole piece;
Activate the magnetic coupling, so as to “suck” the second extending element off the tray and into position on the pole piece.
   Such a set-up does not require additional arms, tools, etc., but instead naturally exploits a (simple modification of) a, structure (the specimen holder) that is already present. Of course, such an arrangement is not compulsory, and one can instead contrive many possible alternatives/variants, which may, if desired/required, make use of an assistive robot arm, for example.

Some examples will now be given of the wide variety of possible extending elements that can be used in the present invention. Although not limiting upon the scope of the present application, an important category of extending element has the form of a hollow, truncated cone, whose conical axis is intended to lie substantially along the abovementioned particle-optical axis. This truncated cone has a relatively wide end (for mounting against the pole piece) and a relatively narrow end (to be disposed proximal the specimen).

Its walls are metallic, and define an emergence aperture at said narrow end, through which the beam of charged particles can pass so as to impinge upon the specimen. Such a design has several variables, including:
Its length, measured along its conical axis between said wide and narrow ends. This will ultimately determine the working distance to the specimen.
The external and internal diameters of its narrow end.
The material/constitution of the walls.
In optical column designs that employ an internal booster tube (acceleration tube), additional variables are the position/form of the wall of the extending element relative to the booster tube.
   Regardless of its particular geometry, the inventive extending element can, for example, be used to achieve (one or more of) the effects set forth hereunder:
   (a) Altering a profile of the electromagnetic field(s) in the final lens of the particle-optical column, and thereby modifying (geometric) properties of the charged particle beam traversing it. More specifically:
In a magnetic final lens, the extending element extends the magnetic pole piece of the lens so as to bring it closer to the specimen.
In an electrostatic final lens, the extending element extends the electrode structure of the lens (e.g. three nested coaxial electrodes, with the middle electrode at high potential and the outer and inner electrodes at lower/ground potential) so as to bring it closer to the specimen.

### Examples Include:

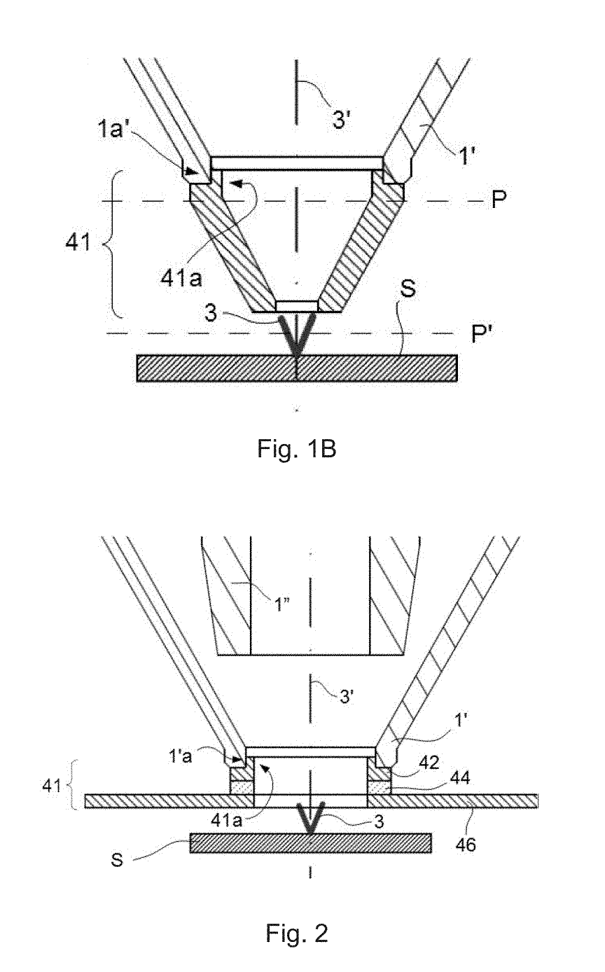

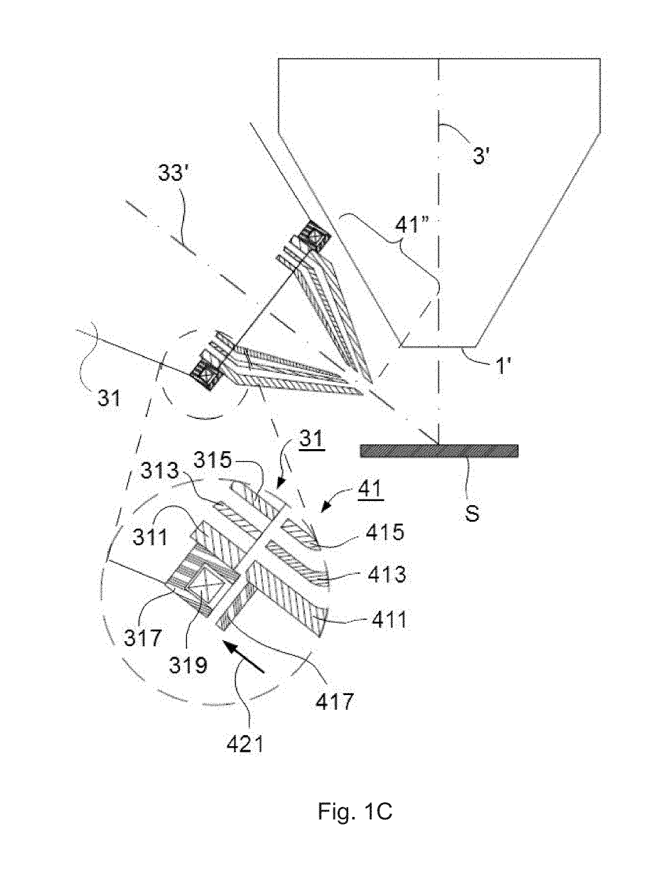

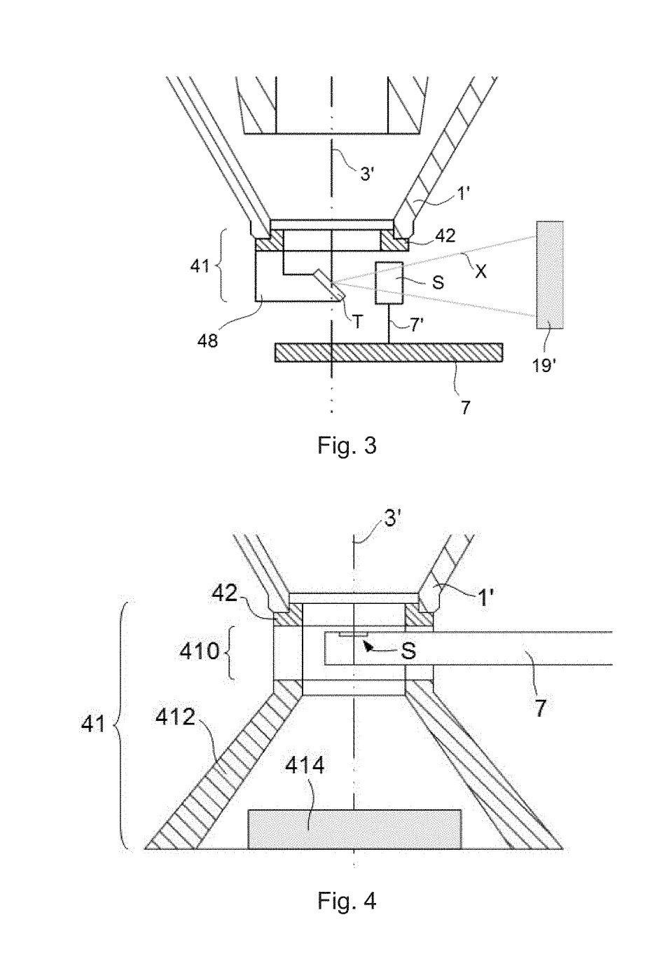

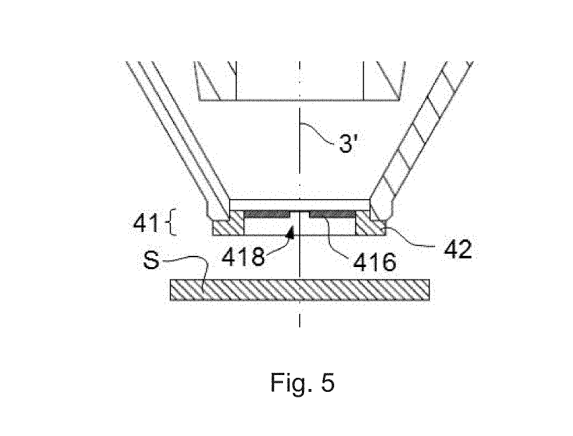

(a)(i) Extending the focal length of the column/shifting its main optical plane closer to the specimen, thereby reducing aberrations/improving resolution (see FIG. 1B, for example).
(a)(ii) Increasing a Field of View (FoV) of the microscope, e.g. using a strong electrostatic lens and suitable choice of scanning pivot point.
(a)(iii) Creating a non-immersion magnetic lens close to (just above) the specimen. This can, for instance, be achieved by embodying a final portion of the extending element (just above the specimen) to be comprised of a body of magnetic material that includes an orbital non-magnetic gap (centered on the particle-optical axis/beam); field lines emerging from the gap then have a lensing effect on the beam (see FIG. 2, for example). Here, the main plane of the final lens of the column is shifted toward the specimen.
(a)(iv) In a FIB-SEM, the distance from the FIB column to the specimen holder is typically (significantly) greater than that from the electron column to the specimen holder, due to lack of free space in the vicinity of the specimen. As a result, an ion beam on its way from the FIB column to the specimen tends to broaden out somewhat, generally resulting in a larger-than-optimal spot size on the specimen. An extending element according to the invention can extend the FIB column—in the form of a relatively narrow sleeve (that takes up relatively little space)—so as to bring it significantly closer to the specimen, thereby mitigating the abovementioned beam broadening effect (see FIG. 1C, for example). A (much) narrower ion beam at specimen level allows much finer ion polishing of the specimen, for instance.
(b) The extending element can (regardless of its basic geometric form) act as a holder for a shield (cap, hood, blind). Such a shield can, for example, be used in a dual-beam tool to shield/protect internal elements of the electron column from debris produced during specimen modification (e.g. high-throughput FIB milling) using the ion column. In a variant, a shield may, if desired, be finely perforated (with a central beam aperture), in which case it can act as a pressure limiting member, serving tot control an internal pressure in the optical column relative to an environmental pressure. See FIG. 5, for example.
(c) The extending element can act as a holder for an active electrical device (AED) that is configured to interact with at least one of the beam and the specimen. In specific examples:
(c)(i) The AED is a detector, such as a (segmented) annular detector, for sensing radiation emanating from the specimen. In another such example, the AED is a camera, which (for instance) allows a visual image of the specimen to be formed from the same perspective as a corresponding charged-particle image.
(c)(ii) The AED is a charge-suppression device, such as an electrically biased grid and/or ring.
(c)(iii) The extending element is used to create a rudimentary STEM/TSEM (==Transmissive SEM). In this case:
The extending element includes an extension of the magnetic circuit similar to that described in (a)(iii) above, but now a TEM specimen on a TEM holder is held in the orbital nonmagnetic gap—which thus acts as a specimen bay. The part under the nonmagnetic gap is now a counterpole.
The AED is a charged-particle detector arrangement located beneath (i.e. on the beam emergence side of) said counterpole.
   See FIG. 4, for example.
   (d) The extending element can act as a holder for an X-ray tomography target. In such a scenario, an arm holds a metallic target in the path of the charged particle beam, causing X-rays to be produced when the beam impinges upon the target. In this way, a CPM can be used to perform X-ray tomography (micro-CT/nano-CT; CT=Computer Tomography) on a specimen, such as a mineralogical sample, for instance (see FIG. 3, for example).

The easy exchangeability of a wide variety of extending elements offered by the present invention opens the possibility of conveniently using several different extending elements during a single workflow/use session of the CPM. In other words, while viewing/processing a given specimen with a given particle-optical column, it is possible to swap extending element one or more times, so as to achieve different viewing/processing effects. Specific (non-limiting) examples in this regard include the following:

Preparation of (TEM) Lamella Using a FIB:
At first using an extending element that has a main plane relatively far from the specimen, and employing a relatively high-energy broad beam for rough preliminary work;
Then using an extending element that has a main plane relatively close to the specimen, allowing aberration control even when a low-energy, smaller beam footprint is used for fine finishing work.
Using a SEM with several extending elements that yield successively different imaging resolutions—e.g. first coarse (at a large field of view), then intermediate, then fine (for sub-nanometer resolution).

It should be noted that, in the context of the present invention, the particle-optical column may be designed/configured such that it will only operate satisfactorily/within parameters when an extending element (chosen from a wide scala of different types/functions/forms) is attached thereto.

The invention will now be elucidated in more detail on the basis of exemplary embodiments and the accompanying schematic drawings, in which:

FIG. 1A renders a longitudinal cross-sectional view of an embodiment of a CPM in which the present invention is implemented.

FIG. 1B renders a magnified view of a portion of the subject of FIG. 1A, and depicts a particular embodiment of a column extending element according to the present invention.

FIG. 1C renders a magnified view of a different portion of the subject of FIG. 1A, and depicts a particular embodiment of another column extending element according to the present invention.

FIG. 2 shows an alternative embodiment—to that shown in FIG. 1B—of a column extending element according to the present invention.

FIG. 3 illustrates a different embodiment of a column extending element according to the present invention.

FIG. 4 illustrates another embodiment of a column extending element according to the present invention.

FIG. 5 illustrates yet another embodiment of a column extending element according to the present invention.

In the Figures, where pertinent, corresponding parts may be indicated using corresponding reference symbols.

### EMBODIMENT 1

FIG. 1A is a highly schematic depiction of an embodiment of a CPM in which the present invention is implemented; more specifically, it shows an embodiment of a microscope M, which, in this case, is a FIB-SEM (though, in the context of the current invention, it could just as validly be a SEM, (S)TEM, or ion-based microscope, for example). The microscope M comprises a particle-optical column (illuminator) 1, which produces a beam 3 of input charged particles (in this case, an electron beam) that propagates along a particle-optical axis 3′. The column 1 is mounted on a vacuum chamber 5, which comprises a specimen holder 7 and associated actuator(s) 7′ for holding/positioning a specimen S. The vacuum chamber 5 is evacuated using vacuum pumps (not depicted). With the aid of voltage supply 17, the specimen holder 7, or at least the specimen S, may, if desired, be biased (floated) to an electrical potential with respect to ground. The column 1 (in the present case) comprises an electron source 9 (such as a Schottky gun, for example), lenses 11, 13 to focus the electron beam 3 onto the specimen S, and a deflection unit 15 (to perform beam steering/scanning of the beam 3). The column 1 has a terminal pole piece 1′ at an extremity facing said specimen holder 7. The microscope M further comprises a controller/computer processing apparatus 25 for controlling inter alia the deflection unit 15, lenses 11, 13 and detectors 19, 21, and displaying information gathered from the detectors 19, 21 on a display unit 27.

The detectors 19, 21 are chosen from a variety of possible detector types that can be used to examine different types of emergent radiation emanating from the specimen S in response to irradiation by the input beam 3. In the apparatus depicted here, the following (non-limiting) detector choices have been made:
Detector 19 is a solid state detector (such as a photodiode) that is used to detect cathodoluminescence emanating from the specimen S. It could alternatively be an X-ray detector, such as Silicon Drift Detector (SDD) or Silicon Lithium (Si(Li)) detector, for example.
Detector 21 is an electron detector in the form of a Solid State Photomultiplier (SSPM) or evacuated Photomultiplier Tube (PMT), for example. This can be used to detect backscattered and/or secondary electrons emanating from the specimen S.
   The skilled artisan will understand that many different types of detector can be chosen in a set-up such as that depicted, including, for example, an annular/segmented detector. By scanning the input beam 3 over the specimen S, emergent radiation—comprising, for example, X-rays, infrared/visible/ultraviolet light, secondary electrons (SEs) and/or backscattered electrons (BSEs)—emanates from the specimen S. Since such emergent radiation is position-sensitive (due to said scanning motion), the information obtained from the detectors 19, 21 will also be position-dependent. This fact allows (for instance) the signal from detector 21 to be used to produce a BSE image of (part of) the specimen S, which image is basically a map of said signal as a function of scan-path position on the specimen S.
   The signals from the detectors 19, 21 pass along control lines (buses) 25′, are processed by the controller 25, and displayed on display unit 27. Such processing may include operations such as combining, integrating, subtracting, false colouring, edge enhancing, and other processing known to the skilled artisan. In addition, automated recognition processes (e.g. as used for particle analysis) may be included in such processing.

In addition to the electron column 1 described above, the microscope M also comprises an ion-optical column 31. In analogy to the electron column 1, the ion column 31 comprises an ion source 39 (such as a Knudsen cell, for example) and imaging optics 32, and these produce/direct an ion beam 33 along an ion-optical axis 33′. The column 31 has a terminal pole piece (electrode) 31′ at an extremity facing said specimen holder 7. To facilitate easy axis to specimen S on holder 7, the ion axis 33′ is canted relative to the electron axis 3′. As hereabove described, such an ion (FIB) column 31 can be used to perform processing/machining operations on the specimen S, such as incising, milling, etching, depositing, etc.

As here depicted, the CPM M makes use of a manipulator arm A, which can be actuated in various degrees of freedom by actuator system A′, and can (if desired) be used to assist in transferring specimens to/from the specimen holder 7, e.g. as in the case of a so-called TEM lamella excised from the specimen S using ion beam 33.

Alternatively/supplementally, this manipulator arm A (or another one like it) can be used in the specific context of the present invention, to assist in mounting/swapping/demounting of extending elements 41 (see below).

It should be noted that many refinements and alternatives of such a set-up will be known to the skilled artisan, including, for instance, the use of a, controlled environment at the specimen S, e.g. maintaining a pressure of several mbar (as used in an Environmental SEM or low-pressure SEM) or by admitting gases, such as etching or precursor gases, etc.

In accordance with the current invention, at least one of the pole pieces 1′/31′ is provided with an exchangeable column extending element 41, which is magnetically mounted on said pole piece 1731′ so as to face (specimen S on) specimen holder 7. This extending element 41 can have a variety of forms/functionalities (see above), and will be described in more detail below. In the current embodiment, said magnetic mounting is achieved by:
Embodying at least an upper portion of extending element 41 (facing pole piece 1′) to comprise ferromagnetic material;
Exploiting pole piece 1′ as an electromagnet which, when energized, will firmly hold extending element 41 in place.

As here depicted, the microscope M also comprises an in situ library 43 for storing a variety of different extending elements 41′. In this particular embodiment, this library 43 comprises a tray 45 on which various extending elements 41′ are arranged in respective parking locations, and this tray 45 is attached to/co-moved with specimen holder 7; however, this does not have to be the case, and the library 43 might instead take the form of a rack or carrousel, for example, and/or not be connected to the holder 7. In order to swap/exchange a stored extending element 41′ for a deployed extending element 41, one can, for example, proceed as follows:
Use the manipulator arm A to de-mount extending element 41 from pole piece 1′/31′; move it to a vacant parking location on tray 45 and deposit it thereon; pick up a different extending element 41′ from tray 45, move it to pole piece 1′/31′ and mount it thereon; and/or
Move tray 45 so as to position a vacant parking location along axis 3′/33′ of pole piece 1′/31′; disable the magnetic coupling between deployed extending element 41 and pole piece 1′/31′, causing extending element 41 to be released from pole piece 1′/31′ and set down on said parking location; move tray 45 so as to position parked extending element 41′ along axis 3′/33′ of pole piece 1′/31′; activate said magnetic coupling, so as to cause extending element 41′ to be sucked up from its parking location and adhered to pole piece 1′/31′.

Turning now to FIG. 1B, this renders a magnified view of a portion of the subject of FIG. 1A, and depicts a particular embodiment of a column extending element 41 according to the present invention. More particularly, the Figure shows (tapering) pole piece 1′, which has a circumferential recess 1′a on a “receiving” side facing specimen S and centered on beam axis 3′. The column extending element 41 is a hollow cone having walls comprised of ferromagnetic material (such as Permalloy) with a circumferential protrusion/lip 41a on a “mating” side thereof, and this is dimensioned so as to sit into (engage/mate with) said recess 1′a, thereby auto-aligning/centering the extending element 41 on axis 3′. The ferromagnetic walls of element 41 are magnetically attracted to the pole piece 1′ when the particle-optical column 1 is energized, thereby firmly clamping/mounting the extending element 41 to the pole piece 1′. The effect of the extending element 41 is to lower a main particle-optical plane of column 1—moving it from an initial level P to a shifted level P′—and thereby effectively increase the column's focal length. Concurrently, imaging aberrations are reduced and resolution is enhanced. See example (a)(i) above.

FIG. 1C, shows an alternative/supplemental situation to that depicted in FIG. 1B, in that an inventive extending element 41″ is magnetically mounted to ion column 31 as opposed to electron column 1. The extending element 41″ is a tapered hollow cone, whose walls comprise a nested set of three electrodes 411, 413 and 415 (which may, for example, respectively be at low potential/ground, high potential and low potential/ground). When the extending element 41″ is engaged with pole piece 31, these electrodes 411, 413, 415 mate with corresponding electrodes 311, 313, 315 in pole piece 31, thus forming electrical interconnects between the pole piece 31 and the extending element 41″. These various electrodes may, for example, comprise a metal such as titanium. To effect the magnetic mounting in this case, note that:
The pole piece 31 is provided with an annular yoke 317 of ferromagnetic material, which is centered on axis 33′ and has a U-shaped cross-section at the end of a given radius. Within this yoke 317, an annular electrical coil 319 is arranged.
The extending element 41″ is provided with a cooperating flange 417 of ferromagnetic material, which is positioned and dimensioned so as to engage with yoke 317 and close it (converting the aforementioned cross-section from “U” to “O”) when the extending element is mated with pole piece 31 (by insertion in the direction of arrow 421).
An electrical current passed through coil 319 will magnetize the yoke portions 317, 417, clamping them to one another. The closed magnetic circuit formed by closed mated yoke portions 317, 417 will prevent magnetic field lines from coil 319 from interfering with an ion beam travelling along axis 33′.
   As in FIG. 1B, the effect of the arrangement in FIG. 1C is to lower a main particle-optical plane of column 31 and thereby effectively increase the column's focal length. This, in turn, creates an ion beam that is focused into a smaller spot. See example (a)(iv) above

### EMBODIMENT 2

FIG. 2 renders a magnified view of a portion of the subject of FIG. 1A, and depicts a different embodiment of a column extending element 41 to that shown in FIG. 1B. More particularly, the Figure shows (tapering) pole piece 1′, within which is located a booster tube 1″. As in FIG. 1B, the element 41 has (on an upper/mating side thereof) a circumferential protrusion/lip 41a that engages in an auto-aligning manner with a circumferential recess 1′a on (a lower/receiving side of) pole piece 1′. In this particular instance, the extending element 41 has the following structure:
An upper collar 42 of ferromagnetic material (such as Permalloy);
A lower plate 46 of ferromagnetic material;
An interposed spacer 44 of non-ferromagnetic material.
   The upper collar 42 is magnetically attracted to the pole piece 1′ when the particle-optical column 1 is energized, thereby firmly clamping/mounting the extending element 41 to the pole piece 1′. At the same time, the presence of the non-magnetic spacer 46 will force magnetic field lines passing from collar 42 to plate 46 to exit the element 41 at the location of the spacer 44, thereby creating a non-immersion magnetic lens just above the specimen S. See example (a)(iii) above.

### EMBODIMENT 3

FIG. 3 illustrates a different embodiment of a column extending element 41 according to the present invention, which in this case is a holder for an X-ray tomography (micro-CT/nano-CT) target T. Once again, the element 41 has a ferromagnetic collar 42 that engages with pole piece 1′ in an auto-aligning manner. Attached to collar 42 is an arm 48 that holds a metallic target T upon axis 3′. An electron beam travelling along axis 3′ will impinge upon target T, causing a flux X of X-rays to be produced. The specimen holder 7 has been modified (by incorporation of stand 7′) to hold a specimen S in the flux X, which passes through specimen S and falls upon X-ray detector 19′. In this way, the CPM M can be used to perform X-ray tomography on a specimen S, which may be a mineralogical, crystallographic, semiconductor or biological sample, for instance. See example (d) above.

### EMBODIMENT 4

FIG. 4 illustrates another embodiment of a column extending element 41 according to the present invention, which in this case is an adapter used to create a rudimentary STEM/TSEM. Once again, the element 41 has a ferromagnetic collar 42 that engages with pole piece 1′ in an auto-aligning manner. Below 42, a bay 410 (vacant space) has been created into which specimen holder 7 can be inserted, so as to position specimen S on axis 3′. Below this bay 410 is a counterpole 412 (comprising ferromagnetic material) on which is mounted a STEM camera 414. See example (c)(iii) above.

### EMBODIMENT 5

FIG. 5 illustrates yet another embodiment of a column extending element according to the present invention, which in this case is a shielding element. Within ferromagnetic collar 42, a shielding plate 416 has been mounted, with a small aperture 418 centered on axis 3′. Such a construction can, for example:
Shield/protect internal elements of the electron column 1 from debris produced during specimen modification (e.g. high-throughput FIB milling) using the ion column 31 (see FIG. 1A);
Act as an atmospheric gas barrier, to help maintain the inside of column 1 at a high vacuum level when the microscope M is used in environmental/low-pressure mode (with gas in the vicinity of specimen S). See example (b) above.

In view of the many possible embodiments to which the disclosed principles may be applied, it should be recognized that the illustrated embodiments are only preferred examples and should not be taken as limiting the scope of protection. Rather, the scope of protection is defined by the following claims.

We claim:

1. A charged-particle microscope having a vacuum chamber comprising:
a specimen holder for holding a specimen;
a particle-optical column for producing and directing a beam of charged particles along an axis so as to irradiate the specimen, the column having a terminal pole piece at an extremity facing the specimen holder;
a detector for detecting a flux of radiation emanating from the specimen in response to irradiation by the beam; and
an exchangeable column extending element magnetically mounted on the pole piece in a space between the pole piece and the specimen holder.

2. A microscope according to claim 1, wherein:
a receiving face of the pole piece is provided with a first mechanical aligning feature; and
a mating face of the extending element is provided with a second mechanical aligning feature;
wherein the first and second mechanical aligning features engage with each other so as to cause the extending element to be held in a pre-defined position on the pole piece.

3. A microscope according to claim 2, wherein the pre-defined position is substantially centered on the axis.

4. A microscope according to claim 2, wherein:
the receiving face is provided with a first set of utilities interconnects;
the mating face is provided with a second, corresponding set of utilities interconnects;
wherein when the mechanical aligning features are engaged, the first and second sets of utilities interconnects are coupled to one another, so as to allow transfer of utilities between the pole piece and the extending element.

5. A microscope according to claim 1, wherein an interface between the pole piece and the extending element forms a, vacuum seal.

6. A microscope according to claim 1, wherein the extending element comprises material that is not permanently magnetic, and is held in place on the pole piece by a magnetic field emanating from the pole piece.

7. A microscope according to claim 1, wherein the extending element comprises an electromagnetic member that can be activated to effect the magnetic mounting.

8. A microscope according to claim 1, further comprising:
an in situ library for storing a variety of different extending elements;
an exchanger mechanism for de-mounting a first extending element from the pole piece and storing the first extending element in the library; and
retrieving a second extending element from the library and mounting the second extending element on the pole piece.

9. A microscope according to claim 8, wherein the specimen holder comprises at least part of the exchanger mechanism.

10. A microscope according to claim 1, wherein the microscope is a dual-beam microscope comprising:
an electron-optical column, for producing an electron beam and directing the electron beam so as to irradiate the specimen; and
an ion-optical column for producing an ion beam and directing the ion beam so as to irradiate the specimen,
wherein the extending element is mounted on at least one of the particle-optical columns.

11. A microscope according to claim 1, wherein the extending element is configured to alter a profile of an electromagnetic field emerging from the particle-optical column toward the specimen.

12. A microscope according to claim 1, wherein the extending element is configured to produce at least one effect selected from the group comprising:
at least partially shielding an interior space of the particle-optical column from an environment exterior to the column;
positioning an active electrical device proximal the specimen, which device is configured to interact with at least one of the beam and the specimen; or
positioning a metallic target on the axis, to act as an X-ray source when impinged upon by the beam.

13. A method of using a charged-particle microscope, comprising:
providing a specimen on a specimen holder;
using a particle-optical column to produce and direct a beam of charged particles along an axis so as to irradiate the specimen, the column having a terminal pole piece at an extremity facing the specimen holder;
using a detector, for detecting a flux of radiation emanating from the specimen in response to irradiation by the beam; and
magnetically mounting an exchangeable column extending element on the pole piece in a space between the pole piece and the specimen holder prior to irradiating the specimen.

14. A method according to claim 13, wherein an exchanger mechanism is used to retrieve the extending element from an in situ library for storing a variety of different extending elements and to mount a retrieved extending element on the pole piece.

15. A method according to claim 14, wherein during a use session of the microscope on a particular specimen, the exchanger mechanism is used to perform one or more exchanges of the extending element for one or more other extending elements stored in the library.

16. A charged-particle microscope having a vacuum chamber comprising:
a specimen holder for holding a specimen;
a particle-optical column for producing and directing a beam of charged particles along an axis so as to irradiate the specimen, the column having a terminal pole piece at an extremity facing the specimen holder; and
an exchangeable column extending element magnetically mounted on the pole piece in a space between the pole piece and the specimen holder.

17. A microscope according to claim 16, wherein:
a receiving face of the pole piece is provided with a first mechanical aligning feature; and
a mating face of the extending element is provided with a, second mechanical aligning feature;
wherein the first and second mechanical aligning features engage with each other so as to cause the extending element to be held in a pre-defined position on the pole piece.

18. A microscope according to claim 17, wherein the pre-defined position is substantially centered on the axis.

19. A microscope according to claim 17, wherein:
the receiving face is provided with a first set of utilities interconnects;
the mating face is provided with a second, corresponding set of utilities interconnects;
wherein when the mechanical aligning features are engaged, the first and second sets of utilities interconnects are coupled to one another, so as to allow transfer of utilities between the pole piece and the extending element.

20. A microscope according to claim 17, wherein the extending element comprises an electromagnetic member that can be activated to effect the magnetic mounting.
